(19) United States
(12) Patent Application Publication
(10) Pub. No.: US 2017/0171981 A1
(43) Pub. Date: Jun. 15, 2017

(54) METHOD OF FABRICATING SUBSTRATE STRUCTURE

(71) Applicant: Siliconware Precision Industries Co., Ltd., Taichung (TW)

(72) Inventors: Chun-Hsien Lin, Taichung (TW); Shih-Chao Chiu, Taichung (TW); Yu-Cheng Pai, Taichung (TW); Tzu-Chieh Shen, Taichung (TW); Chia-Cheng Chen, Taichung (TW)

(21) Appl. No.: 15/393,429

(22) Filed: Dec. 29, 2016

Related U.S. Application Data
(62) Division of application No. 14/607,572, filed on Jan. 28, 2015, now abandoned.

(30) Foreign Application Priority Data
Sep. 12, 2014 (TW) 103131511

(51) Int. Cl. H05K 3/00; H05K 3/28; H05K 3/46; H05K 3/18; H05K 3/40

(52) U.S. Cl. CPC H05K 3/007; H05K 3/188; H05K 3/4038; H05K 3/4682; H05K 3/0026; H05K 3/28; H05K 2203/1377

(57) ABSTRACT

The present invention provides a substrate structure and a method of fabricating the substrate structure. The method includes: forming a first wiring layer on a first carrier, forming a dielectric layer on the first wiring layer, forming a second wiring layer on the dielectric layer, forming an insulating protection layer on the second wiring layer, forming a second carrier on the insulating protection layer, and removing the first carrier. The formation of the second carrier provides the substrate structure with adequate rigidity to avoid breakage or warpage such that the miniaturization requirement can be satisfied.

### CROSS-REFERENCE TO RELATED APPLICATIONS

This application is a divisional of copending application U.S. Ser. No. 14/607,572, filed on Jan. 28, 2015, which claims under 35 U.S.C. §119(a) the benefit of Taiwanese Application No. 103131511, filed Sep. 12, 2014, the entire contents of which are incorporated herein by reference.

### BACKGROUND OF THE INVENTION

1. Field of the Invention

The present invention relates to substrate structures and methods of fabricating the same, and, more particularly, to a substrate structure that has warpage and thickness reduced, and a method of fabricating the same.

2. Description of Related Art

With the advancement in electronic industry, the demand for low-profile electronic products is increasing. In order to meet the low-profile requirement, reducing the substrate thickness is one of the major areas of development. However, the method of fabricating a substrate structure currently still fails to effectively reduce the substrate thickness. Please refer to FIGS. 1A-1D illustrating a method of fabricating a conventional substrate structure 1.

As shown in FIG. 1A, a carrier 10 is provided, then a seed layer 11 is formed on the carrier 10, and a first wiring layer 12 is formed on the seed layer 11.

As shown in FIG. 1B, a dielectric layer 13 is formed on the first wiring layer 12, and a plurality of holes 14 are formed in the dielectric layer 13 and expose a portion of the first wiring layer 12. A sputtering process is then performed to form a second seed layer 15 on the dielectric layer 13, the holes 14 and the exposed portion of the first wiring layer 12. Subsequently, a patterned resist layer 18 is formed on a portion of the second seed layer 15, with the other portion of the second seed layer 15 exposed. A second wiring layer 16 is formed on the exposed portion of the second seed layer 15 by an electroplating method, and is electrically connected with the first wiring layer 12.

As shown in FIG. 1C, the carrier 10 and the seed layer 11 are removed, to expose the first wiring layer 12.

As shown in FIG. 1D, the patterned resist layer 18 is removed, and an insulating protection layer 19 such as solder mask is formed on two opposing surfaces of the dielectric layer 13, so as to complete the fabrication process of the substrate structure 1.

However, in the prior art of fabricating the substrate structure 1, in order to provide sufficient rigidity and prevent deformation during transportation, packaging or other processes, the dielectric layer 13 must be sufficiently thick after the carrier 10 and the seed layer 11 are removed, or an insulating protection layer 19 has to be additionally formed on the two sides of the substrate structure 1. As a result, either the dielectric layer 13 or the insulating protection layer 19 has the limitation of minimum thickness, which does not meet the low-profile requirement for electronic products.

Thus, there is an urgent need for providing the aforementioned problems in the prior art.

### SUMMARY OF THE INVENTION

In view of the aforementioned drawbacks, the present invention provides a method of fabricating a substrate structure, comprising: forming on a first carrier a first wiring layer having opposing first and second surfaces, with the first surface of the first wiring layer coupled to the first carrier; forming on the second surface of the first wiring layer a dielectric layer that has at least one hole exposing a portion of the first wiring layer; forming a second wiring layer on the dielectric layer, and forming in the at least one hole, from which the portion of the first wiring layer is exposed, at least a conductive via that is electrically connected to the second wiring layer and the first wiring layer; forming on the dielectric layer and the second wiring layer an insulating protection layer that has at least one opening that exposes a portion of the second wiring layer; forming a second carrier on the insulating protection layer; and removing the first carrier.

The present invention further provides a substrate structure, comprising: a dielectric layer having opposing top and bottom surfaces and at least one hole formed in the dielectric layer and communicating with the bottom surface; a first wiring layer embedded in the dielectric layer and exposed from the top surface of the dielectric layer; a second wiring layer formed on the bottom surface of the dielectric layer; at least a conductive via formed in the at least one hole and electrically connected with the first wiring layer and the second wiring layer; an insulating protection layer formed on the bottom surface of the dielectric layer and the second wiring layer and having at least one opening that exposes a portion of the second wiring layer; and a carrier being in contact with and carrying the insulating protection layer.

Accordingly, the substrate structure and the method of fabricating the same according to the present invention feature in an increased rigidity provided by the carrier formed on the insulating protection layer and the second wiring layer. As a result, the problems of the prior art, such as deformation, fragmentation, and warpage to the substrate, can be effectively solved. Therefore, it is possible to reduce the thickness of the dielectric layer and the solder mask, so as to meet the low-profile requirement.

### BRIEF DESCRIPTION OF DRAWINGS

FIGS. 1A-1D are schematic views illustrating a method of fabricating a conventional substrate structure;

FIGS. 2A-2I are schematic views illustrating a method of fabricating a substrate structure according to the present invention; and

FIGS. 3A-3I are schematic views illustrating another method of fabricating a substrate structure according to the present invention.

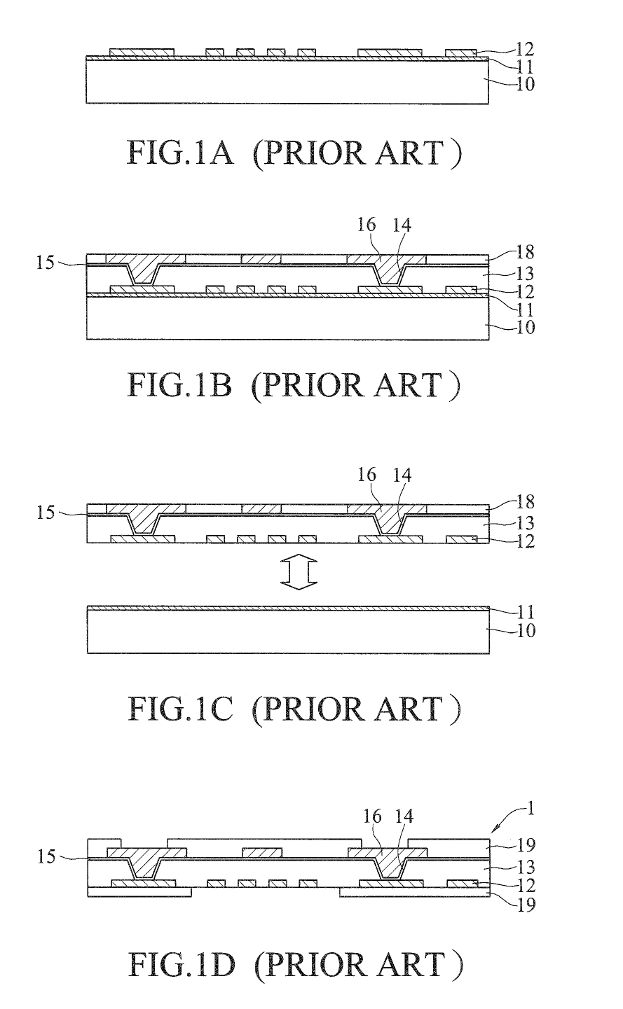

### DETAILED DESCRIPTION OF PREFERRED EMBODIMENTS

The present invention is described in the following with specific embodiments, so that one skilled in the pertinent art can easily understand other advantages and effects according to the present invention from the disclosure according to the present invention.

It should be noted that all the drawings are not intended to limit the present invention. Various modification and variations can be made without departing from the spirit according to the present invention. Further, terms, such as “first”, “second”, “top” and “bottom” etc., are merely for illustrative purpose and should not be construed to limit the scope according to the present invention.

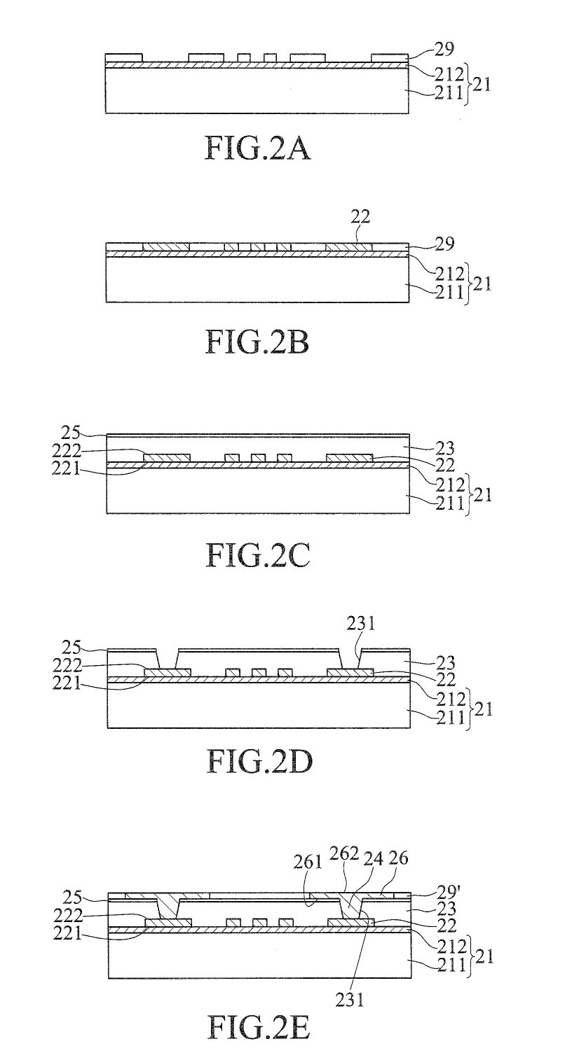

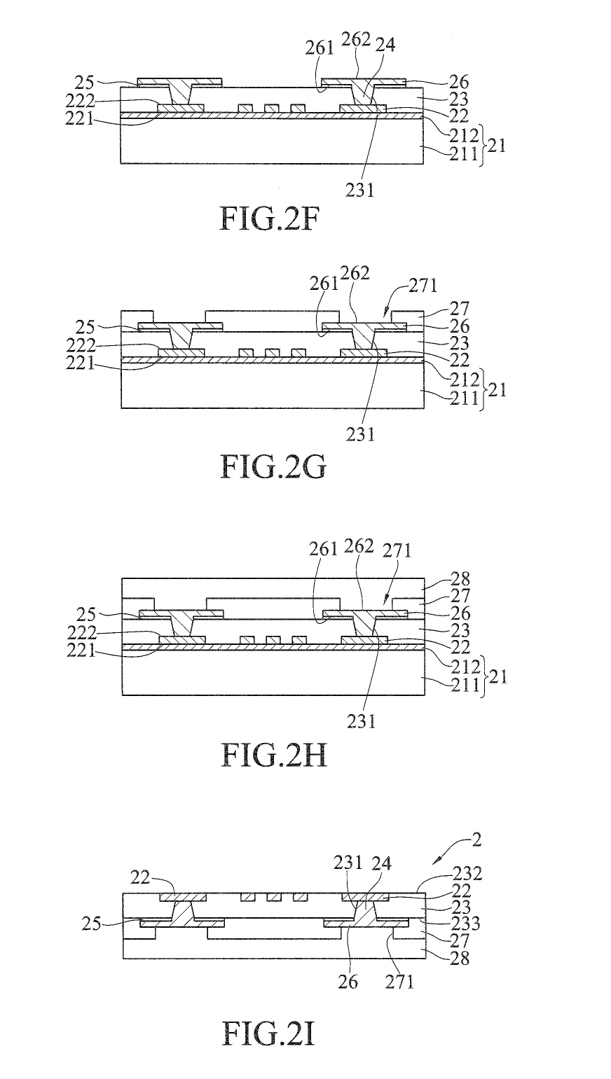

FIGS. 2A-2I are schematic views illustrating a method of fabricating a substrate structure according to the present invention. As shown in FIG. 2A, a first carrier 21 is provided. In an embodiment, the first carrier 21 comprises a main body 211 and a first seed layer 212 formed on the main body 211. Subsequently, a patterning resist layer 29 is formed on a portion of the first seed layer 212, with the other portion of the first seed layer 212 exposed.

As shown in FIG. 2B, a first wiring layer 22 is formed on the exposed portion of the first seed layer 212.

As shown in FIG. 2C, the first wiring layer 22 has opposing first and second surfaces 221 and 222, and the first surface 221 is coupled with the first seed layer 212. In an embodiment, a first wiring layer 22 is directly formed on the main body 211 of the first carrier 21, and the first surface 221 of the first wiring layer 22 is coupled with the main body 211 of the first carrier 21.

Subsequently, the patterned resist layer 29 is removed, to form a dielectric layer 23 on the second surface 222 of the first wiring layer 22 and the first seed layer 212, and a second seed layer 25 is formed on the dielectric layer 23.

In an embodiment, an electro-less or sputtering method is used to form the first seed layer 212 or the second seed layer 25, and the first seed layer 212 or the second seed layer 25 is made of copper.

As shown in FIG. 2D, the dielectric layer 23 has at least one hole 231 that exposes a portion of the first wiring layer 22. In an embodiment, the hole 231 is formed on the second seed layer 25 towards the dielectric layer 23 by laser drilling or mechanical drilling method.

As shown in FIG. 2E, after the hole 231 is formed, a patterned resist layer 29′ is formed on a portion of the second seed layer 25. The patterned resist layer 29′ does not cover the hole 231, and exposes the second seed layer 25. A second wiring layer 26 and a conductive via 24 are formed on the exposed portion of the second seed layer 25 and in the hole 231 by an electroplating method. The second wiring layer 26 has a first surface 261 and a second surface 262. The conductive via 24 is electrically connected to the second surface 222 of the first wiring layer 22 and the first surface 261 of the second wiring layer 26. In an embodiment, the second wiring layer 26 is directly formed on the dielectric layer 23, and the first surface 261 of the second wiring layer 26 is coupled with the dielectric layer 23.

As shown in FIG. 2F, the patterned resist layer 29′ and a portion of the second seed layer 25 underneath the patterned resist layer 29′ are removed.

As shown in FIG. 2G, an insulating protection layer 27 is formed on the dielectric layer 23 and a portion of the second surface 262 of the second wiring layer 26. The insulating protection layer 27 is formed with at least one opening 271 that exposes a portion of the second surface 262 of the second wiring layer 26.

In an embodiment, the insulating protection layer 27 is made of a solder mask.

As shown in FIG. 2H, a second carrier 28 is formed on the insulating protection layer 27 and the exposed portion of the second surface 262 from the opening 271. In other words, the opening 271 is filled with a portion of the second carrier 28, and the second carrier 28 is in contact with and carries the insulating protection layer 27.

As shown in FIG. 2I, the first carrier 21, i.e., the main body 211 and first seed layer 212, is removed, so as to complete the fabrication of the substrate structure 2 according to the present invention.

In an embodiment, the main body 211 of the first carrier 21 is made of glass or metal. The second carrier 28 is made of an adhesive material or a release material, or other materials that can be easily detached and removed. The second carrier 28 can be removed after a chip is bonded and molded, which is then followed by subsequent processes (such as ball placement).

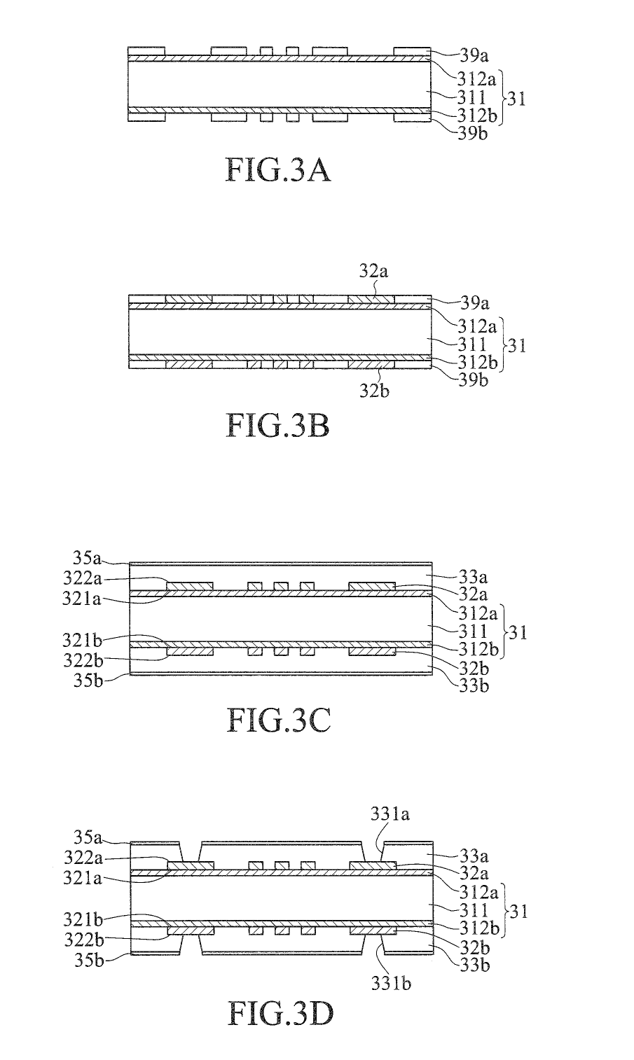

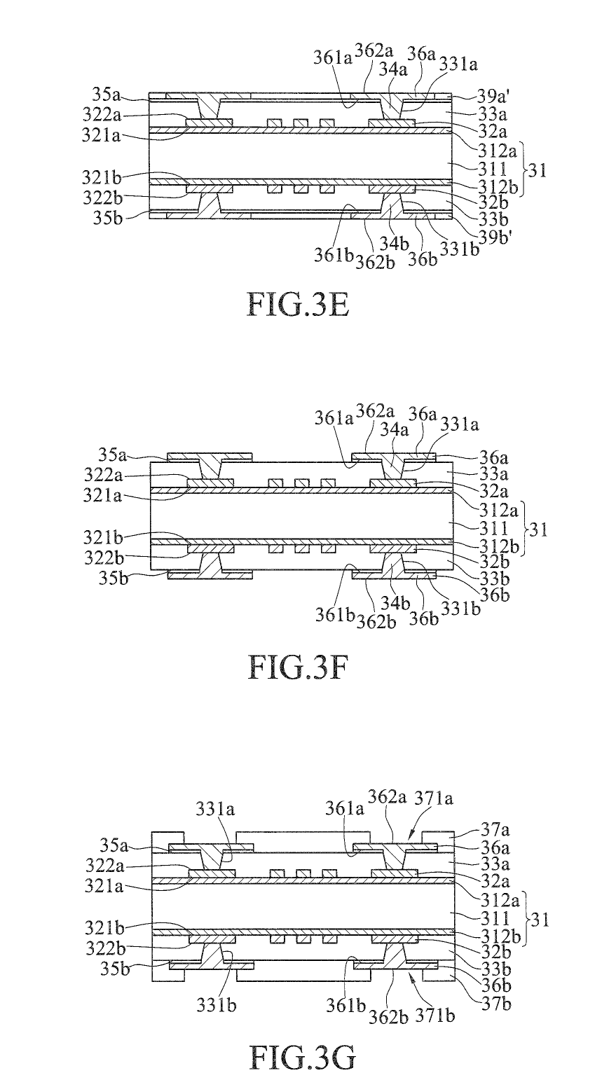

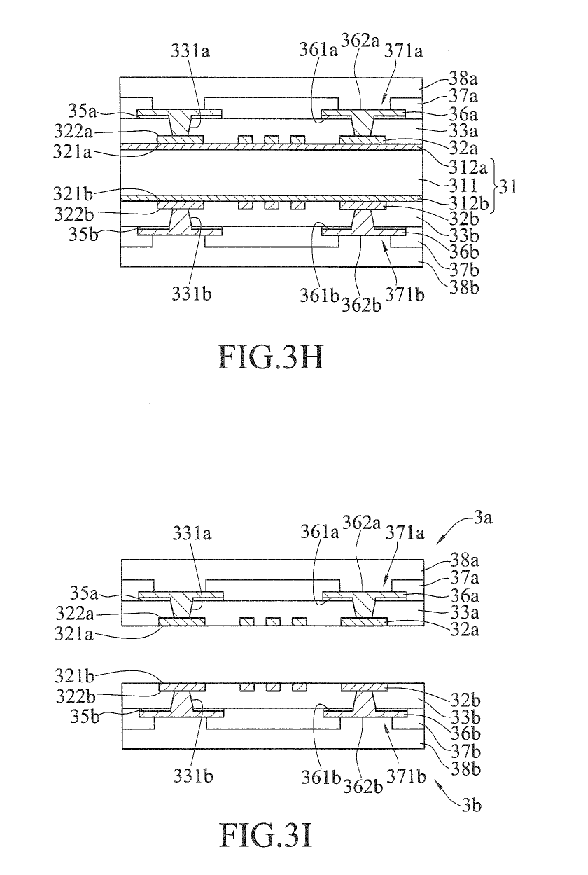

FIGS. 3A-3I are schematic views illustrating another method of fabricating a substrate structure according to the present invention.

As shown in FIG. 3A, a first carrier 31 is provided. The first carrier 31 has two opposing sides. In an embodiment, the method is characterized in that the first wiring layer, the dielectric layer, the second wiring layer, the insulating protection layer and the second carrier are formed on the two sides.

First seed layers 312a and 312b are formed on the two sides of the main body 311 of the first carrier 31, respectively. Subsequently, patterned resists layers 39a and 39b are formed on a portion of the seed layers 312a and 312b, with the other portion of the first seed layers 312a and 312b exposed.

As shown in FIG. 3B, first wiring layers 32a and 32b are formed on the exposed portions of the first seed layers 312a and 312b, respectively, by an electroplating method.

As shown in FIG. 3C, a first wiring layer 32a has opposing first and second surfaces 321a and 321b, a first wiring layer 32b has opposing first and second surfaces 321b and 322b. The first surfaces 321a and 321b are coupled to the first seed layers 312a and 312b, respectively. In an embodiment, the first wiring layers 32a and 32b are directly formed on the two sides of the main body 311 of the first carrier 31, with the first surfaces 321a and 321b of the first wiring layers 32a and 32b coupled to the main body 311 of the first carrier 31.

After the patterned resist layers 39a and 39b are removed, the dielectric layers 33a and 33b are formed on the second surfaces 322a and 322b of the first wiring layers 32a and 32b, respectively, and second seed layers 35a and 35b are formed on the dielectric layers 33a and 33b, respectively.

In an embodiment, the seed layers 312a and 312b or the second seed layers 35a and 35b are formed by electro-less or sputtering method, and the seed layers 312a and 312b or the second seed layers 35a and 35b are made of copper.

As shown in FIG. 3D, holes 331a and 331b are formed in the dielectric layers 33a and 33b, respectively, with a portion of the second surfaces 322a and 322b of the first wiring layers 32a and 32b exposed.

In an embodiment, the holes 331a and 331b are formed from the second seed layers 35a and 35b towards the dielectric layers 33a and 33b by laser drilling or mechanical drilling.

As shown in FIG. 3E, after the holes 331a and 331b are formed, the patterned resist layers 39a′ and 39b′ are formed on the second seed layers 35a and 35b, respectively, and do not cover the openings 331a and 331b, with a portion of the second seed layers 35a and 35b exposed. The second wiring layers 36a and 36b and the conductive vias 34a and 34b are formed on the exposed portions of the second seed layers 35a and 35b and the holes 331a and 331b, respectively. The second wiring layers 36a and 36b have respective first surfaces 361a and 361b and second surfaces 362a and 362b. The conductive vias 34a and 34b are electrically connected with the second surfaces 322a and 322b of the first wiring layers 32a and 32b and the first surfaces 361a and 361b of the second wiring layers 36a and 36b, respectively. In an embodiment, the second wiring layers 36a and 36b are directly formed on the dielectric layers 33a and 33b, respectively, with the first surfaces 361a and 361b of the second wiring layers 36a and 36b coupled with the dielectric layers 33a and 33b.

As shown in FIG. 3F, the patterned resist layers 39a′ and 39b′ and portions of the second underneath seed layers 35a and 35b are removed.

As shown in FIG. 3G, the insulating protection layers 37a and 37b are formed on the dielectric layers 33a and 33b and on portions of the second surfaces 362a and 362b of the second wiring layers 36a and 36b, respectively. Openings 371a and 371b are formed on the insulating protection layers 37a and 37b, respectively, with portions of the second surfaces 362a and 362b of the second wiring layers 36a and 36b exposed.

In an embodiment, the insulating protection layers 37a and 37b are made of a solder mask.

As shown in FIG. 3H, the second carriers 38a and 38b are formed on the insulating protection layers 37a and 37b and on portions of the second surfaces 362a and 362b of the second wiring layers 36a and 36b exposed from the openings 371a and 371b, respectively. In other words, the openings 371a and 371b are filled with portions of the second carriers 38 and 38b, respectively, which are in contact with and carry the insulating protection layers 37a and 37b.

As shown in FIG. 3I, the first carrier 31, i.e., the main body 311 and first seed layers 312a and 312b, is removed, so as to complete the fabrication of the two substrate structures 3a and 3b according to the present invention.

In an embodiment, the main body 311 of the first carrier 31 is made of glass or metal. The second carriers 38a and 38b are made of an adhesive material or a release material, or other materials that can be easily detached and removed. The second carriers 38a and 38b can be removed after a chip is bonded and molded, which is then followed by subsequent processes (such as ball placement).

In a method of fabricating a substrate structure according to the present invention, two sides of the main body 311 of the first carrier 31 are simultaneously fabricated to form the substrate structure 3a, 3b, such that the cost is saved.

Referring to FIG. 2I, the present invention provides a substrate structure 2, comprising a first wiring layer 22, a dielectric layer 23, a second seed layer 25, a second wiring layer 26, an insulating protection layer 27 and a second carrier 28.

The dielectric layer 23 has opposing top and bottom surfaces 232 and 233, and at least one hole 231 is formed in the dielectric layer 23 and communicates with the bottom surface 233.

The first wiring layer 22 is embedded in the dielectric layer 23 and exposed from the top surface 232 of the dielectric layer 23. In an embodiment, the first wiring layer 22 is flush with the top surface 232 of the dielectric layer 23.

The second wiring layer 26 is formed on the bottom surface 233 of the dielectric layer 23, and a second seed layer 25 is formed between the bottom surface 233 of the dielectric layer 23 and the second wiring layer 26. At least a conductive via 24 is formed in the at least a hole 231 of the dielectric layer 23, and electrically connected with the first wiring layer 22 and the second wiring layer 26.

The insulating protection layer 27 is formed on the bottom surface 233 of the dielectric layer 23 and the second wiring layer 26. The insulating protection layer 27 has at least one opening 271 that exposes a portion of the second wiring layer 26. The insulating protection layer 27 is made of a solder mask.

The second carrier 28 is in contact with and carries the insulating protection layer 27, and the opening 271 of the insulating protection layer 27 is filled with a portion of the second carrier 28. The second carrier 28 is made of an adhesive material or a release material, or other materials that can be easily detached or removed.

The present invention provides a substrate structure and a method of fabricating the same, wherein a second carrier is formed after an insulating protection layer is formed, followed by removing the first carrier. The second carrier provides the rigidity to avoid substrate from deformation, breakage or warpage in the subsequent processes during transportation, packaging and other processes. Moreover, the dielectric layer can be thinned from 80 μm to 60 μm for instance. In comparison with prior art, the method of fabricating the present invention eliminates the disposition of the insulating protection layer, in other words, disposing an insulating protection layer on two sides of the substrate structure is not necessary, thereby having the advantages of increased product reliability and lowered cost.

The present invention has been described using exemplary preferred embodiments. However, it is to be understood that the scope according to the present invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A method of fabricating a substrate structure, comprising:
forming on a first carrier a first wiring layer having opposing first and second surfaces, with the first surface of the first wiring layer coupled to the first carrier;
forming on the second surface of the first wiring layer a dielectric layer that has at least one hole exposing a portion of the first wiring layer;
forming a second wiring layer on the dielectric layer, and forming in the at least one hole, from which the portion of the first wiring layer is exposed, at least a conductive via that is electrically connected to the second wiring layer and the first wiring layer;
forming on the dielectric layer and the second wiring layer an insulating protection layer that has at least one opening that exposes a portion of the second wiring layer;
forming a second carrier on the insulating protection layer; and
removing the first carrier.

2. The method of claim 1, wherein the first carrier comprises a main body and a seed layer formed on the main body, and the first wiring layer is formed on the seed layer.

3. The method of claim 2, wherein the first wiring layer is formed by:
forming a patterned resist layer on the seed layer, with a portion of the seed layer exposed from the patterned resist layer and the first wiring layer formed on the exposed portion of the first seed layer; and
removing the patterned resist layer.

4. The method of claim 1, wherein the second wiring layer and the conductive via are formed by:
forming the dielectric layer on the second surface of the first wiring layer;
forming a second seed layer on the dielectric layer;
laser drilling or mechanical drilling the second seed layer and the dielectric layer to form at least one hole that exposes the portion of the first wiring layer; and
forming the second wiring layer on the second seed layer, and forming the at least a conductive via in the at least one hole, from which the portion of the first wiring layer is exposed.

5. The method of claim 4, further comprising, prior to forming the second wiring layer, forming a patterned resist layer on the second seed layer, with a portion of the second seed layer exposed from the patterned resist layer and the second wiring layer formed on the exposed portion of the second seed layer, and removing the patterned resist layer.

6. The method of claim 1, wherein the insulating protection layer is made of a solder mask.

7. The method of claim 1, wherein the second carrier is made of an adhesive material or a release material.

8. The method of claim 1, wherein the second carrier is in contact with and carries the insulating protection layer, and the opening is filled with a portion of the second carrier.

9. The method of claim 1, wherein the first carrier has two opposing sides, and the first wiring layer, the dielectric layer, the second wiring layer, the insulating protection layer and the second carrier are formed on the two sides of the first carrier.

10-15. (canceled)
